(19) United States
(12) Patent Application Publication
(10) Pub. No.: US 2008/0118009 A1
(43) Pub. Date: May 22, 2008

(54) Pseudo-random number demodulation circuit of receiving device of wireless communication system

(76) Inventors: Yu-Min Chuang, Hsinchu City (TW); Fu-Min Yeh, Taoyuan City (TW); Juinn-Horng Deng, Pingjhen City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/601,765

(22) Filed: Nov. 20, 2006

(51) Int. Cl. H03D 1/00; H04L 27/06

(52) U.S. Cl. 375/340

(57) ABSTRACT

The present invention relates to a pseudo-random number demodulation circuit of receiving device of wireless communication system. More particularly, it can demodulate the symbol data transmitted from a transmitting device for a wireless communication system. The transmitting device modulates multiple pilot subcarriers and multiple data subcarriers of the symbol data according to a first PN. The present invention uses a first demodulator demodulates all pilot subcarriers and data subcarriers of the symbol data according to a second PN. Further, a splitter splits the symbol data to the pilot subcarriers and the data subcarriers. More, a second demodulator is used to demodulate the data subcarriers according to a third PN. Therefore, the present invention can demodulate the pilot subcarriers and the data subcarriers which have not been modulated.

### FIELD OF THE INVENTION

The present invention relates to a pseudo-random number demodulation circuit of receiving device of wireless communication system. More particularly, it is directed to pseudo-random number (PN) demodulation circuit of a receiving device for a wireless communication system.

### BACKGROUND OF THE INVENTION

The development of communication systems currently is toward to a century of wireless communication systems. Most conventional wireless communication systems use the demodulation circuit of the receiving device as shown in FIG. 1 to modulate the output data of the transmitting device according to a pseudo-random number (PN). Multi-Band Orthogonal Frequency Division Multiplexing Ultra Wide Band (MB-OFDM UWB) system is one example in the present invention. Please refer to FIG. 1. It is a block diagram showing one conventional transmitting device for a wireless communication system. As can be seen from FIG. 1, the conventional transmitting device 10 has a first modulator 12, a second modulator 14, and an Inverse Fast Fourier Transform (IFFT) unit 16. The first modulator 12 modulates and inputs multiple pilot subcarriers to the transmitting device according to the PN of different pilot subcarriers corresponding to different symbol data. The modulated pilot subcarriers are transmitted to the IFFT unit 16. The second demodulator 14 demodulates and inputs multiple data subcarriers to the transmitting device according to PN of the data subcarriers corresponding to different symbol data. Further, the modulated data subcarriers are transmitted to the IFFT unit 16. The Inverse Fast Fourier Transform (IFFT) unit 16 can proceed an IFFT according to the modulated pilot subcarriers and data subcarriers for a symbol data. The symbol data includes a header data and a payload data.

Please refer to FIG. 2. FIG. 2 is one conventional wireless communication system showing symbol data versus PN. As can seen from the figure, the transmitting device and the receiving device of the conventional communication system can modulate and demodulate multiple symbol data according to multiple pseudo-random numbers PN in order to apply in different kinds of wireless communication systems. Multi-Band Orthogonal Frequency Division Multiplexing Ultra Wide Band (MB-OFDM UWB) system is one of the examples in the present invention. The symbol data individually include a header data and a payload data. Each header data and each payload data include multiple pilot subcarriers and multiple data subcarriers. In the first symbol data, all pilot subcarriers of the header data are multiplied by P1. More, no matter if the transmission rate exceeds 200M bits per second, all pilot subcarriers of the payload data are multiplied by P7. In the third symbol data, all pilot subcarriers of the header data are multiplied by P2. When the data transmission rate does not exceed 200M bits per second, all pilot subcarriers of the payload data are multiplied by P8. When the data transmission rate exceeds 200M bits per second, all the pilot subcarriers of the payload data are multiplied by P9.

In the second symbol data, all pilot subcarriers of the header data are multiplied by P1 and P7, and all data subcarriers are multiplied by P7. When the data transmission rate does not exceed 200M bits per second, all pilot subcarriers of the payload data are multiplied by P7 and P13, and all data subcarriers are multiplied by P13. When the data transmission rate exceeds 200M bits per second, all pilot subcarriers of the payload data are multiplied by P8. In the 4^{th} symbol data, all pilot subcarriers of the header data are multiplied by P2 and P8, and all data subcarriers are multiplied by P8. When the data transmission rate does not exceed 200M bits per second, all pilot subcarriers of the payload data are multiplied by P8 and P14, and all data subcarriers are multiplied by P14. When the data transmission rate exceeds 200M bits per second, all pilot subcarriers of the payload data are multiplied by P10. Therefore, a phase-shift estimate unit of the receiving device can obtain the corresponding phase-shift value of each data subcarrier according to each pilot subcarrier. Further, the receiving device can adjust each data subcarrier to the original input data according each phase-shift value.

No matter in header data or payload data, all pilot subcarriers or data subcarriers are mixed together. When the receiving device demodulates the symbol data, it requires determining the addresses of all pilot subcarriers. In other words, the number of subcarriers for the header data and the payload data of each symbol data is required continuously counting for determining the pilot subcarriers as well as proceeding demodulation. For example, one pilot subcarrier is set for every 10 subcarriers. However, not every transmission data is counted in this way. More complicated determination always increases the complexity of the demodulation circuit, and further decreases the performance of the demodulation circuit.

Therefore, the present invention is to provide a pseudo-random number demodulation circuit of receiving device of wireless communication system as well as to provide a simplifier circuit. More, the present invention does not need to determine the storage address of the pilot subcarrier, and further enhance the performance of the demodulation circuit.

### SUMMARY OF THE INVENTION

The main object of the present invention is to provide a pseudo-random number demodulation circuit of receiving device of wireless communication system. More particularly, it first demodulates all subcarriers according to a PN. Then, it demodulates all data subcarriers according to a second PN. Therefore, it can individually demodulate all pilot subcarriers and all data subcarriers.

The present invention is directed to a pseudo-random number demodulation circuit of receiving device of wireless communication system. It has a first demodulator, a splitter, and a second demodulator. The first demodulator demodulates all pilot subcarriers and all data subcarriers of the symbol data in the receiving device according to multiple first PN. The splitter splits the pilot subcarriers and the data subcarriers from the demodulated symbol data, and the data subcarriers are transmitted to the second demodulator. The second demodulator demodulates the output data subcarriers of the splitter according to multiple second PN. Therefore, the receiving device of the present invention can enhance the performance of multiple symbol data. Further, the receiving device of the present invention has a FFT unit, a phase-shift estimate unit, and a data detector. The FFT unit can fast transform and input symbol data to the receiving device. The phase-shift estimate unit can produce multiple corresponding phase-shift values according to the pilot subcarriers. The data detector detects the data subcarriers for producing the corresponding data according to the phase-shift value.

Other objects, advantages, and novel features of the invention will become more apparent from the following detailed description when taken in conjunction with the accompanying drawings.

### BRIEF DESCRIPTION OF THE DRAWINGS

FIG. 1 is a block diagram showing one conventional transmitting device for a wireless communication system;

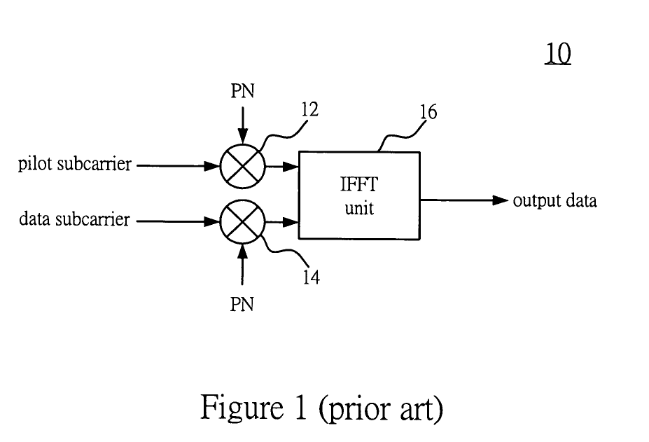

FIG. 2 is a conventional communication system showing symbol data versus PN;

FIG. 3 is one preferred embodiment in the present invention showing a receiving device with a block diagram;

FIG. 4A is one of the preferred embodiments in the present invention showing symbol data versus PN; and

FIG. 4B is another preferred embodiment in the present invention showing symbol data versus PN.

### DETAILED DESCRIPTIONS OF THE INVENTION

Each of the forgoing examples merely illustrates some applications for the present invention. It is understood that the invention is not limited to such embodiments. Other features and advantages of the present invention will become apparent from the following detailed description of the invention made with reference to the accompanying drawings.

The present invention relates to a pseudo-random number (PN) demodulation circuit of a receiving device for a wireless communication system as well as provides a simplifier demodulation circuit. More, the present invention can fast demodulate multiple symbol data which have been modulated by a transmitting device of a wireless communication system according to multiple PN. Each symbol data includes a header data and a payload data. The header data and the payload data individually include multiple pilot subcarriers and multiple data subcarriers. The demodulation circuit of the present invention, therefore, can be used in different kinds of wireless communication systems. Multi-Band Orthogonal Frequency Division Multiplexing Ultra Wide Band (MB-OFDM UWB) system is one of the examples in the present invention.

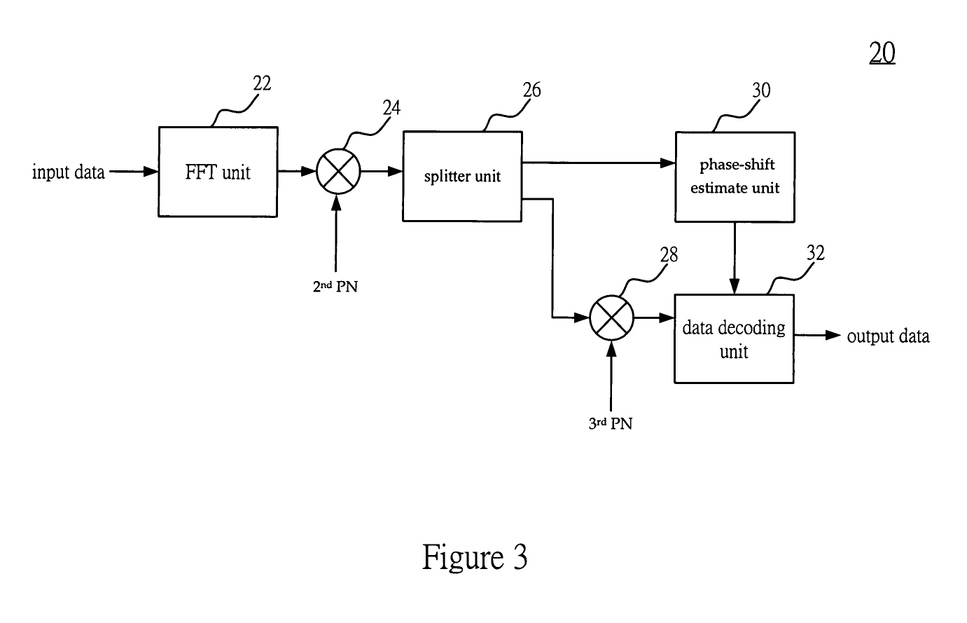

Please refer to FIG. 3. FIG. 3 is one of the preferred embodiments in the present invention showing a receiving device with a block diagram. As can shown in FIG. 3, the receiving device 20 of the present invention has a Fast Fourier Transform (FFT) unit 22, a first demodulator 24, a splitter 26, a second demodulator 28, a phase-shift estimate unit 30, and a data decoding unit 32. FFT unit 22 fast transforms the symbol data as multiple transmitting signals from the transmitting device of the wireless communication system to the receiving device 20. The transmitting device modulates all pilot subcarriers and data subcarriers of the symbol data according to a first PN. Further, the IFFT is used to transform the symbol data to the transmitting signal for sending to the receiving device 20. Besides, different symbol data are corresponding to different first PN. The first modulator 24 demodulates the pilot subcarriers and the data subcarriers according to a second PN. The first demodulator 24 is a multiplier, and can make all pilot subcarriers and data subcarriers multiply by the second PN and demodulates for the original pilot subcarriers. The second PN is corresponding to the first PN.

The splitter 26 is a demultiplexer. The splitter 26 receives the symbol data demodulated by the first demodulator 24. The splitter 26 is used to split the pilot subcarriers and the data subcarriers from the symbol data. The splitter 26 transmits the pilot subcarriers to the phase-shift estimate unit 30. More, the splitter 26 transmits the data subcarriers to the second demodulator 28. The second demodulator 28 demodulates the data subcarriers modulated by the second PN according to a third PN. The second demodulator 28 is a multiplier, and makes the data subcarriers multiply by the third PN and demodulates for the original data subcarriers. The third PN is corresponding to the second PN. The second demodulator 28 transmits the demodulated data subcarriers to the data decoding unit 32. The data decoding unit 32 can detect the recorded data information of the data subcarriers according to the phase-shift estimate unit 30 as well as multiple estimated phase-shift values from the pilot subcarriers. The first PN, the second PN, and the third PN can be 1 or −1.

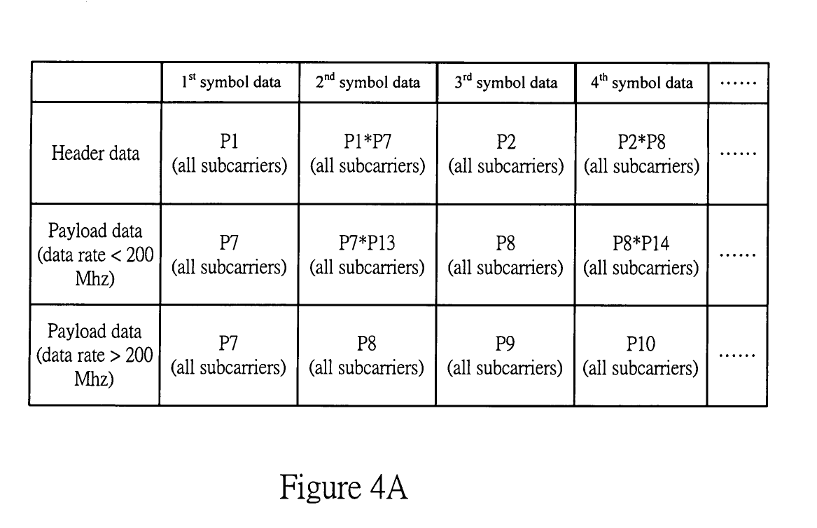

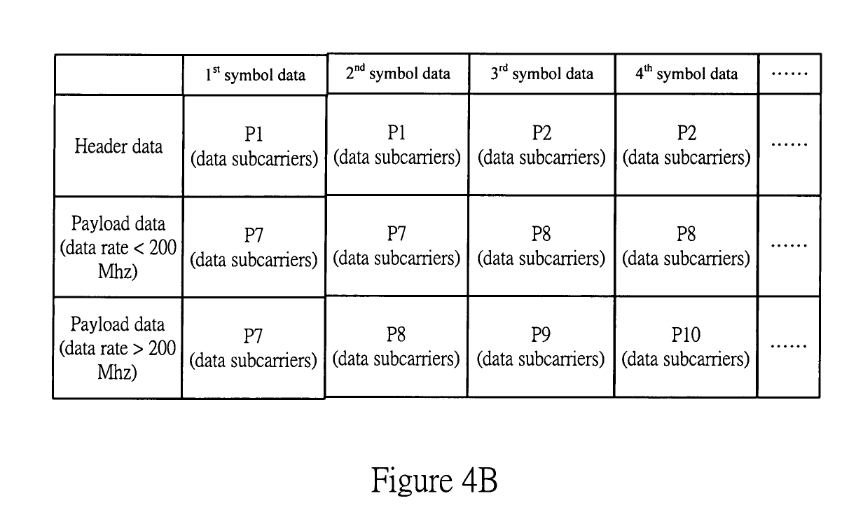

Please refer to FIG. 4A and FIG. 4B. They are two preferred embodiments of the present invention showing symbol data versus PN. As can be seen from figures, the demodulation circuit of the present invention uses different symbol signals to correspond to different first PN, uses the second PN to correspond to the first PN, and uses the third PN to correspond to the second PN in order to have the pilot subcarriers and data subcarriers demodulated by the first demodulator 24 and the second demodulator 28. As shown in FIG. 4A, the first demodulator 24 of the present invention demodulates all pilot subcarriers and data subcarriers of different symbol data according to different symbol data as well as different corresponding second PN. The second PN as shown in FIG. 4A is used for multiplying PN of all subcarriers. Therefore, the first symbol data is from all subcarriers demodulated by P1, the second symbol data is from all subcarriers demodulated by P1 and P7, the third symbol data is from all subcarriers demodulated by P2, and the 4^{th} symbol data is from all subcarriers demodulated by P2 and P8.

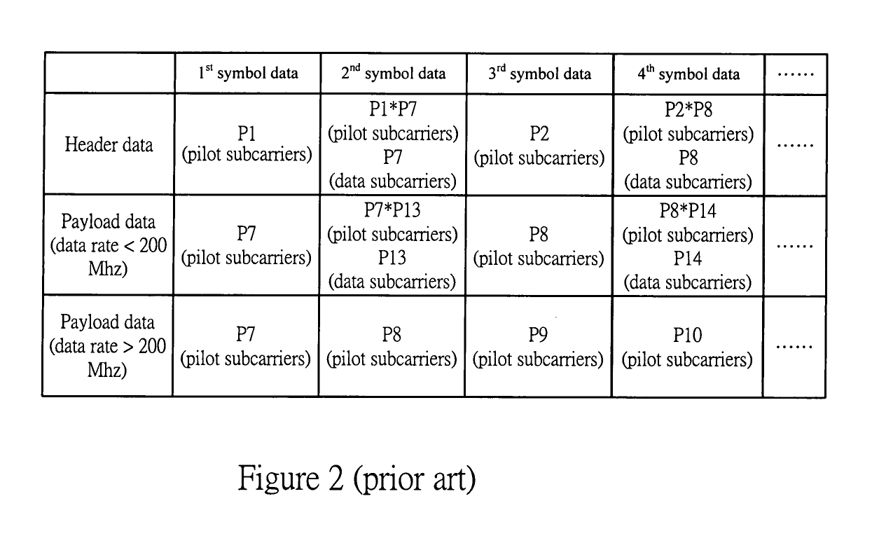

As can be seen from FIG. 4B, the second demodulator 28 of the present invention corresponds to the third PN according to different symbol data, and demodulates all data subcarriers of different symbol data. The third PN in FIG. 4B is calculated from multiplication of the PN in FIG. 2 and the second PN in FIG. 4A. The header data of the first symbol data is from the data subcarrier demodulated by P1. The header data of the second symbol data is from the data subcarrier demodulated by P1. The header data of the third symbol data is from the data subcarrier demodulated by P2. The header data of the 4^{th} symbol data is from the data subcarrier demodulated by P2. When the data transmission rate does not exceed 200 MHz per second, the payload data of the first symbol data is from the data subcarriers demodulated by P7, the payload data of the second symbol data is from the data subcarriers demodulated by P7, the payload data of the third symbol data is from the data subcarriers demodulated by P8, and the payload data of the 4^{th} symbol data is from the data subcarriers demodulated by P8. When data transmission rate exceeds 200 MHz per second, the first symbol data is from the data subcarriers demodulated by P7, the second symbol data is from the data subcarriers demodulated by P8, the third symbol data is from the data subcarriers demodulated by P9, and the 4^{th} symbol data is from the data subcarriers demodulated by P10.

According to the above description, the present invention is to provide a PN demodulation circuit of a receiving device for a wireless communication system. More, the present invention relates a PN demodulation technique mixed with regular pilot subcarriers and data subcarriers. The demodulation technique can simplify the PN demodulation circuit of the receiving device. Further, the demodulation circuit first uses the first demodulator to demodulate all pilot subcarriers and data subcarriers according to all PN of pilot subcarriers and data subcarriers. Then, the PN of the data subcarriers in the receiving device are used to demodulate the data subcarriers of all demodulated subcarriers.

While the invention is susceptible to various modifications and alternative forms, specific embodiments thereof have been shown by way of example in the drawings and detailed description. It should be understood, however, that the drawings and detailed description thereto are not intended to limit the invention to the particular form disclosed, but, on the contrary, the invention is to cover all modifications, equivalents and alternatives falling within the spirit and scope of the present invention as defined by the claims. As may be seen, the described embodiments may be modified in many different ways without departing from the scope or teachings of the invention. Similarly, any combination of the teachings herein may be modified to achieve similar but different results.

What is claimed is:

1. A pseudo-random number demodulation circuit of receiving device of wireless communication system, which is applicable to a symbol data of a transmitting device for a wireless communication system, wherein said transmitting device demodulating said symbol data according to a first pseudo-random number and the pseudo-random number demodulation circuit of receiving device of wireless communication system comprising:
a first demodulator demodulating a plurality of pilot subcarriers and a plurality of data subcarriers of a symbol data according to a second pseudo-random, and said second pseudo-random corresponding to said first pseudo-random;
a splitter splitting said pilot subcarriers and said data subcarriers of said symbol data; and
a second demodulator demodulating said data subcarriers of said splitter according to a third pseudo-random, and said third pseudo-random corresponding to said second pseudo-random.

2. A pseudo-random demodulation circuit as claimed in claim 1, wherein said first demodulator is used for said pilot subcarriers and said data subcarriers multiplying by said second pseudo-random.

3. A pseudo-random demodulation circuit as claimed in claim 1, wherein said second demodulator is used for said data subcarriers multiplying by said third pseudo-random.

4. A pseudo-random demodulation circuit as claimed in claim 1, wherein said second pseudo-random is the same as pseudo-random of said pilot subcarrier of said symbol data modulated by said transmitting device.

5. A pseudo-random demodulation circuit as claimed in claim 1, wherein said first demodulator and second demodulator are multipliers.

6. A pseudo-random demodulation circuit as claimed in claim 1, wherein said transmitting device utilizes different said first pseudo-random to modulate different said symbol data.

7. A pseudo-random demodulation circuit as claimed in claim 1, wherein said first pseudo-random, second pseudo-random, and third pseudo-random are 1 or −1.

8. A pseudo-random demodulation circuit as claimed in claim 1, wherein said first demodulator is coupled with a fast Fourier transform unit, which converts said symbol data and said symbol data by fast Fourier transform are transformed to said first demodulator.

9. A pseudo-random demodulation circuit as claimed in claim 1, wherein said splitter is further coupled with a phase-shift estimate unit, said pilot subcarriers split by said splitter estimates a phase-shift value of said symbol data for transmitting to a data decoding unit, said data decoding unit is coupled with said second demodulator, and decode said data subcarriers demodulated by said second demodulator according to said phase-shift value.

10. A pseudo-random demodulation circuit as claimed in claim 1, wherein said splitter is a demultiplexer.

11. A pseudo-random demodulation circuit as claimed in claim 1, wherein said wireless communication system is a multi-band orthogonal frequency division multiplexing ultra wide band system.
